(19) United States
(12) Patent Application Publication
(10) Pub. No.: US 2026/0267537 A1
(43) Pub. Date: Sep. 10, 2026

(54) DRIVING HIGH-CAPACITY STORAGE DEVICE PERFORMANCE USING CAPACITORS

(71) Applicant: Sandisk Technologies, Inc., Milpitas, CA (US)

(72) Inventors: SAURABH SINGH, Bangalore (IN); AMIT SHARMA, Bangalore (IN)

(73) Assignee: Sandisk Technologies, Inc., Milpitas, CA (US)

(21) Appl. No.: 19/071,958

(22) Filed: Mar. 6, 2025

(51) Int. Cl. G06F 3/06

(52) U.S. Cl. CPC G06F 3/0625; G06F 3/0655; G06F 3/0679

(57) ABSTRACT

A storage device may use power from a capacitor to increase performance. The storage device includes multiple meta-dies, each of which may include a set of dies. One meta-die may be used for host operations at a time and is supplied host power and the other meta-dies are not supplied host power. The storage device also includes a capacitor to provide backup power to complete an ongoing operation during loss of host power. A controller uses host power to perform a host burst write operation on a first subset of dies in a first meta-die. The controller uses power reserved by the capacitor for a second subset of dies in the first meta-die to power dies in a second meta-die. The controller uses capacitor power to erase dies in the second meta-die in parallel with the host burst write operation on the first meta-die.

### BACKGROUND OF THE INVENTION

A storage device may be communicatively coupled to a host and to non-volatile memory including, for example, a NAND flash memory device on which the storage device may store data received from the host. The memory device may include multiple dies which may be divided into physical blocks and the storage device may store data in pages on blocks on the memory device. Data may be stored in the blocks in various formats, with the formats being defined by the number of bits that may be stored per memory cell. For example, a single-level cell (SLC) format may write one bit per memory cell, a multi-level cell (MLC) format may write two bits per memory cell, a triple-level cell (TLC) format may write three bits per memory cell, a quadruple-level cell (QLC) format may write four bits per memory cell, and so on. A format used to store fewer bits per memory cell may be accessed faster than a format used to store more bits per memory cell.

As the capacity of the storage device increases, the number of dies on the storage device may also increase such that the power to the storage device provided by the host may be insufficient to write to all the dies at the same time. When the storage device includes more dies than can be powered under a maximum power limit of host supplied power, a multi meta-die approach may be used wherein a limited number of dies may be operated on in parallel, thereby reducing the peak power consumed at any instant in time. For example, if a system includes sixty-four dies that may be operated in parallel, but because of the host power constraint the system may only support sixteen active dies, sixteen dies may be included in a meta-die. Each meta-die may be an independent unit. In this example, the system may include four meta-dies, one of which may be active at a time.

A controller on the storage device may extend the life of the device by distributing writes evenly across the meta-dies. A meta block on a meta-die may be formed in an interleaved manner, wherein the meta block may include a block from each die in the meta-die. When the controller programs data to a meta block on a first meta-die, at the end of the meta block on the first meta-die, the controller may begin an erase operation on a meta-block on a second meta-die in order to write data on the meta block in the second meta-die. The erase operation may occur in the foreground and the block erase-overheads may cause performance on the storage device to drop. Although the impact of a block erase operation may be present in sustained write operations, the impact of the block erase operation may be significant during burst write operations when the storage device is accessing, for example, a SLC meta-block at a fast rate. To place the erase-overheads in the background such that the erase-overheads may not affect host operations, a pre-erase feature may be used, wherein a certain number of blocks that may be required for benchmarks may be kept in an erase state on a newly installed storage device. The pre-erase feature only allows for high burst writes on a newly installed storage device, and as such, it is a onetime use feature that may have limited practical use. As the capacity of the storage device increases and the burst range increases, having an increased number of SLC/hybrid blocks in pre-erase state might not be possible

When the storage device performs host write operations, the storage device may also perform control write operations wherein the storage device may write control data such as logical-to-physical data to a global address table (GAT). When buffers used to store GAT deltas are full, eviction from the buffers may be triggered. The storage device may wait for GAT delta page write operation to complete before resuming host write operations, possibly stalling host operations and causing performance on the storage device to drop. In some cases, to prevent program and read failures, the storage device may perform exclusive OR (XOR) writes after host write operations. If the dies are busy with, for example, TLC writes and XOR writes are to be performed on, for example, a SLC block, the XOR write must wait for TLC write to complete. Hence, the XOR buffers may not be ready to accommodate more parity and may pause the host write operations until the XOR write is complete, possibly stalling the host operations and causing performance drop on the storage device. A multi-meta-die storage device may have idle dies to perform control write and/or XOR write operations while host write operations are being performed in other dies. However, because of power constraints, the idle dies may not be used.

### SUMMARY OF THE INVENTION

In some implementations, a storage device may use power from a capacitor to increase performance on the storage device. The storage device includes a memory device including multiple meta-dies. Each of the meta-dies may include a set of dies. One meta-die may be used for host operations at a time and is supplied host power and the other meta-dies are not supplied host power. The storage device also includes a capacitor to provide backup power to complete an ongoing operation during loss of host power on the storage device. A controller may use host power to perform a host burst write operation on a first subset of dies in a first meta-die. The controller may use power reserved by the capacitor for a subset of dies in the second meta-die. The controller may use the capacitor power to execute an erase operation on dies in the second meta-die without requesting more power from host, wherein the controller executes the erase operation in parallel with the host burst write operation on the first meta-die,

In some implementations, a storage device may use power from a capacitor to increase performance on the storage device. The storage device includes a memory device including multiple meta-dies. Each of the meta-dies may include a set of dies. One meta-die may be used for host operations at a time and is supplied host power and the other meta-dies are not supplied host power. The storage device also includes a capacitor to provide backup power to complete an ongoing operation during loss of host power on the storage device. A controller may use host power to perform a host burst write operation on a first subset of dies in a first meta-die. The controller may use power reserved by the capacitor for a subset of dies in the second meta-die. The controller may use the capacitor power to execute a control write operation on the die in the second meta-die in parallel with the host burst write operation on a die in the first meta-die.

In some implementations, a method is provided on the storage device for increasing performance on the storage device by using power from a capacitor on the storage device. The method includes providing backup power to a capacitor to complete an ongoing operation during loss of host power on the storage device. The method also includes performing a host burst write operation, using host power, on a first subset of dies in first meta-die and using power reserved by the capacitor for a second subset of dies in the second meta-die. The method further includes executing an erase operation, using capacitor power, on dies in the second meta-die in parallel with the host burst write operation on the first meta-die.

### BRIEF DESCRIPTION OF THE DRAWINGS

FIG. 1 is a schematic block diagram of an example system in accordance with some implementations.

FIG. 2 is another schematic block diagram of an example system showing how host power is supplied to meta-dies in accordance with some implementations.

FIG. 3 is another schematic block diagram of an example system showing how host power and capacitor power are supplied to meta-dies in accordance with some implementations.

FIG. 4 is an example flow diagram for using power from a capacitor to boost the performance of a storage device in accordance with some implementations.

FIG. 5 is another example flow diagram for using power from a capacitor to boost the performance of a storage device in accordance with some implementations.

FIG. 6 is a diagram of an example environment in which systems and/or methods described herein are implemented.

FIG. 7 is a diagram of example components of one or more devices of FIG. 1.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of implementations of the present disclosure.

The apparatus and method components have been represented where appropriate by conventional symbols in the drawings, showing those specific details that are pertinent to understanding the implementations of the present disclosure so as not to obscure the disclosure with details that will be readily apparent to those of ordinary skill in the art.

### DETAILED DESCRIPTION OF THE INVENTION

The following detailed description of example implementations refers to the accompanying drawings. The same reference numbers in different drawings may identify the same or similar elements.

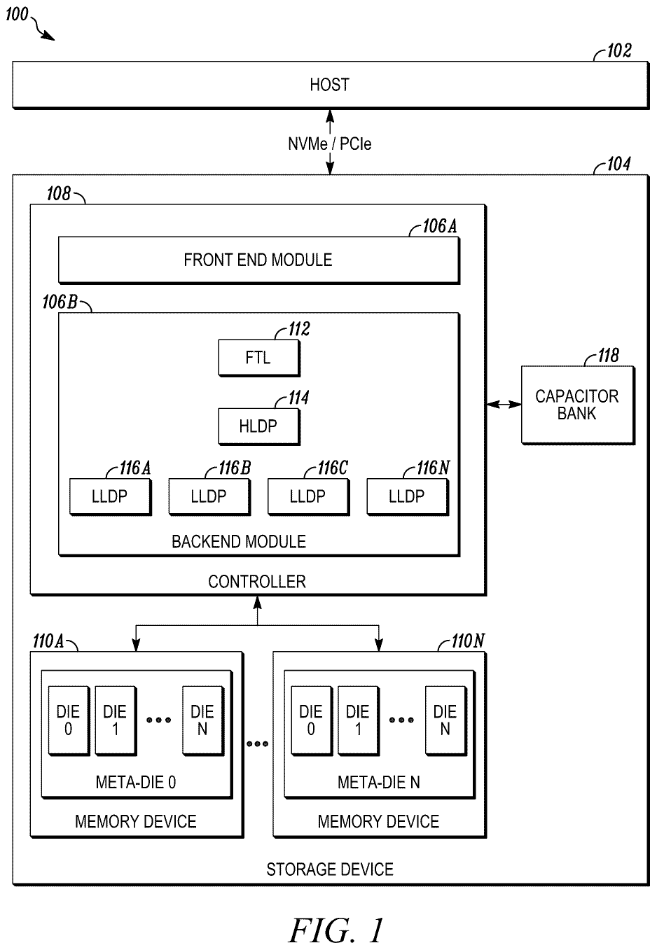

FIG. 1 is a schematic block diagram of an example system in accordance with some implementations. System 100 may include a host 102 and a storage device 104 that may be in the same physical location as components on a single computing device or on different computing devices that are communicatively coupled. Host 102 may provide operational power for storage device 104 and notify storage device 104 about the maximum/peak host power to be used by storage device 104. Storage device 104 may communicate with host 102 via a Non-Volatile Memory Express (NVMe) protocol over a peripheral component interconnect express (PCIe) bus, and the like. Host 102 may include additional components (not shown in this figure for the sake of simplicity).

Storage device 104 may be, for example, a solid-state drive (SSD) that may include a controller 108 and one or more storage components such as non-volatile memory devices 110a-110n (referred to herein as the memory device(s) 110). Controller 108 that may include a front-end module 106a and a backend module 106b. Front-end module 106a may include a host interface module and other components that may be used to interface with host 102. Backend module 106b may include a flash translation layer (FTL) 112, a high-level data path (HLDP) 114, and lower-level data paths (LLDP) 116a-116n that may be used to interface with memory device 110.

Controllers 108 may interface with host 102 and process foreground operations including instructions transmitted from host 102. For example, controllers 108 may read data from and/or write to memory devices 110 based on instructions received from host 102. Controllers 108 may also execute background operations to manage resources on memory device 110. For example, controllers 108 may monitor memory devices 110 and may execute garbage collection and other relocation functions per internal relocation algorithms to refresh, recycle, and/or relocate the data on memory devices 110.

Memory devices 110 may be flash based. For example, memory devices 110 may be a NAND or NOR flash memory that may be used for storing host and control data over the operational life of memory devices 110. Memory devices 110 may include one or more meta-dies (for example, meta-die 0-meta-die N) connected to a memory bus including data lines and chip enable lines. A meta-die may include a number of dies (for example, dies 0-N) that may be operated on in parallel. For example, if system 100 includes sixty-four dies that may be used in parallel, but because of host power constraint, system 100 may only support sixteen active dies, sixteen dies may be included in a meta-die. As such, system 100 may include four meta-dies.

A meta block may be formed in an interleaved manner, wherein the meta block may include a block from each die in the meta-die. Data may be stored in the meta-blocks in various formats, with the formats being defined by the number of bits that may be stored per memory cell. For example, a single-level cell (SLC) format may write one bit per memory cell, a multi-level cell (MLC) format may write two bits per memory cell, a triple-level cell (TLC) format may write three bits per memory cell, a quadruple-level cell (QLC) format may write four bits per memory cell, and so on. A format used to store fewer bits per memory cell may be accessed faster than a format used to store more bits per memory cell. As such, during peak performance when storage device 104 is performing a burst write operation, controller 108 may write data to SLC blocks. During normal/sustained write operations on storage device, controller 108 may write data to blocks that may store more bits per cell than SLC blocks including, for example, TLC blocks. Memory device 110 may be included in storage device 104 or may be otherwise communicatively coupled to storage device 104.

Host 102 may restrict the amount of host power consumed by storage device 104 at a given time. For example, in some protocols, the maximum amount of host power that may be consumed by storage device 104 at a given time may be 7.5 watts (W). With such power restriction when the capacity of storage device 104 increase such that storage device 104 supports multiple meta-dies, only one meta-die may be active at a given time. As such, using the example where storage device 104 includes four meta-dies, when storage device 104 is programming, for example, meta-die 0, the other meta-dies may be placed on an inactive state and may not be supplied host power.

While storage device 104 is writing to a meta-die, an ungraceful shutdown event may occur. For example, storage device 104 may lose host power while it is writing data to meta-die 0. To ensure that the data being written to meta-die 0 is not lost during an ungraceful shutdown when storage device 104 is no longer receiving power from host 102, storage device 104 may also include a capacitor bank 118 with one or more capacitors that may provide backup power for storage device 104 to complete an ongoing operation and avoid a write-abort scenario, wherein write operations may be aborted because of power loss. As such, capacitor bank 118 may provide backup power to hardware components in a write path including hardware components in backend module 106b and meta-die 0 (i.e., the meta-die on which data is being written) when there is an ungraceful shutdown on storage device 104. The other meta-dies that were not being supplied host power when the ungraceful shutdown occurred may continue to remain in an inactive state (i.e., in a state without power).

Storage device 104 may also use capacitor bank 118 as a power booster while storage device 104 is receiving power from host 102. For example, storage device 104 may charge capacitor bank 118 with power supplied by host 102. In an example where a meta-die includes sixteen dies, capacitor bank 118 may be charged with 16-die worth of backup power to carry out a sustained write on all active dies in the meta-die during an ungraceful shutdown (i.e., to write to TLC blocks on the meta-die blocks to complete an ongoing write operation when storage device 104 loses host power). Due to the higher die throughput during a burst write, controller 108 may perform burst writes on a first subset of dies in an active meta-die. During the burst operation, the host power that may be supplied to a second subset of dies (i.e., dies that are not in the first subset of dies in the active meta-die) may not be used for the burst write. With a sixteen die meta-die configuration where a target a burst write may be two gigabytes (GB) per second and a die has a SLC program time of 100 microseconds (μs), controller 108 may perform burst writes with only four dies operating at a time, due to the higher die throughput of approximately 640 megabits (MBps). As such, during a burst operation, the host power that may be supplied to the other twelve dies in the active meta-die may not be used for the burst write.

When the capacitors in capacitor bank 118 are charged, controller 108 may use capacitor bank 118 to power up inactive/dormant dies without drawing more power from host 102. For example, if the power being supplied by host 102 is sufficient to write to meta-die 0 but is insufficient to supply power to other meta-dies, while controller 104 is performing a burst write on the first subset of dies in meta-die 0, storage device 104 may draw power reserved for the second subset of dies in meta-die 0 from capacitor bank 118. Controller 108 may use the power drawn from capacitor bank 118 to power up inactive/dormant dies (i.e., inactive dies on one or more of the meta-dies 1-N,), without drawing extra power from host 102.

To extend the life of the dies on storage device 104, controller 108 may implement wear-leveling, wherein controller 108 may distribute writes evenly across the dies/meta-dies. For example, if host 102 issues a write command with 4 GB of data and controller 108 may write 1 GB to a meta block, controller 108 may write the first GB to a meta block in meta-die 0, the second GB to a meta block in meta-die 1, the third GB to a meta block in meta-die 2, and the fourth GB to a meta block in meta-die 3. While controller is writing the first GB to the meta-block in meta-die 0, storage device 104 may supply host power to meta-die 0 and may not supply host power to the other meta-dies. As such, meta-dies 1-N may be in an inactive/dormant state without host power, when controller 108 is programming meta-die 0.

Prior to programming data on a meta-die, controller 108 may perform an erase operation on the meta-die. For example, when controller 108 is writing the four GB host data to meta-dies 0-3, based on the host operations pending in storage device 104, controller 108 may determine that the host data is to be written to the meta blocks on meta-dies 0-3. As such, controller 108 may determine that the dies in meta-die 1 may have to be erased such that the dies in meta-die 1 may be ready to be programmed after the dies in meta-die 0 have been programmed, that the dies in meta-die 2 may have to be erased such that the dies in meta-die 2 may be ready to be programmed after the dies in meta-die 1 have been programmed, and that the dies in meta-die 3 may have to be erased such that the dies in meta-die 3 may be ready to be programmed after the dies in meta-die 2 have been programmed.

While controller 108 is programing the first GB on the meta-block in meta-die 0, controller 108 may perform an erase operation on meta-die 1 prior to programming the second GB to the meta block on meta-die 1. When controller 108 is performing a burst operation, as noted, a first subset of the dies in the meta-die may be active during the SLC write. For example, four of the dies in meta-die 0 may be active during a burst write. As such, storage device 104 may ensure that capacitor bank 118 reserves 4-die worth of charge from power provided by host 102 to handle an ungraceful abort operation on the burst data being written to the first subset of dies on the active meta-die.

To hide erase overheads when switching from meta-die 0 to meta-die 1, controller 108 may use the remaining 12-die worth of charge that would otherwise be reserved on capacitor bank 118, but that may be unused for burst operations, to begin the erase operation on the meta block in meta die 1. The erase operation on the meta block in meta die 1 using the power provided by capacitor bank 118 may occur in parallel with the burst write on meta-die 0 using the power provided by host 102. In an example where the program time is approximately 100 μs and the erase time is approximately 3 ms, programming of a block would take approximately 8 ms.

Controller 108 may execute multiple burst sessions to fully program an active meta-die. For example, in a sixteen die meta-die configuration where four dies may be programmed during a burst session, controller 108 may execute four burst sessions to fully program the active meta die. When controller 108 is performing a burst write on, for example, the first four dies in meta-die 1 (referred to herein as a first burst session on the active meta-die), controller 108 may use the remaining 12-die worth of capacitor charge to erase the meta-block on a subset of dies in meta-die 1 (the subset of dies on meta-die 1 are referred to herein as a third subset of dies). For example, controller 108 may use the remaining 12-die worth of capacitor charge to erase in the first twelve dies in meta-die 1. When controller 108 is performing a burst write on the next first four dies in meta-die 0 (referred to herein as a second burst session on the active meta-die), controller 108 may use the 4-die worth of capacitor charge associated with the second burst session to erase the remaining section of the meta-block in meta-die 1 that was not erased with the reserved capacitor power associated with the first burst session. For example, controller 108 may use the 4-die worth of capacitor charge to erase the remaining section of the meta-block in the last four dies in meta-die 1. In this example, the erase operations on meta-die 1 may be completed in approximate 3 ms*2 steps, i.e., approximately 6 ms.

If additional capacitors are added to capacitor bank 118, controller 108 may complete the erase process faster. For example, if four capacitors are added to capacitor bank 118, controller 108 may use the reserved 16-die worth of capacitor charge associated with the first burst session to erase the meta-block on the sixteen dies on meta-die 1. As such, controller 108 may complete the erase process in one step taking approximately 3 ms, i.e., controller 108 may complete the erase operation on all the dies in meta-die 1 when executing the first burst session on the active meta-die.

Storage device 104 may have opportunities to charge the capacitors in capacitor bank 118 with ongoing burst programming as the host power being consumed may be for only a subset of the dies (for example, 4-dies) in the active meta-die. As such, controller 108 may perform the parallel erase and burst write operation throughout the life cycle of storage device 104. Controller 108 may thus avoid stalling host operations due to erase operations and may achieve higher burst performance throughout the life cycle of storage device 104, as opposed to performing pre-erase operation only on a newly installed drive as is currently the case in a traditional burst write scheme.

Controller 108 may further avoid stalling host operations due to control write operations including, for example, XOR parity write operations and/or GAT delta write operations. For example, when controller 108 is performing a burst operation on die 0 on meta-die 0, controller 108 may power up, for example, die 0 on meta-die 1 with power from capacitors on capacitor bank 118 and perform the control write operation on die 0 on meta-die 1. Controller 108 may perform the control write operation on die 0 on meta-die 1 in parallel with a host write operation on the dies on meta-die 0. By performing the control write operation in a different meta-die from the meta-die on which the host write is being perform, controller 108 may avoid stalls in the host write path.

An exemplary set of calculations are provided to show that an erase operation may be carried on a subset of dies an inactive meta-die while burst writes are ongoing in an active meta-die. In an example, the time for programming a meta-die with sixteen dies may be 1 millisecond (ms). To protect against an ungraceful write abort situation on a TLC block, storage device 104 may need backup power for 1 ms to complete processing a write operation after a write abort situation occurs, i.e., capacitor bank 118 should provide sufficient power to keep 16-dies in an active state for 1 ms.

If, for ease of calculation, the power required to power up 16 dies is considered to be equal to 100 megawatt (mW), the energy needed may be equal to 100 mW×1 ms, i.e., 100 mW×1000 μs, which is equal to 100000 mW-μs. If storage device 104 is in burst mode at any instant, four dies in a meta-die may be engaged in the burst write and the other twelve dies in the meta-die on which the burst write is taking place may be inactive. The power calculation to protect against a write abort situation on the four dies where the SLC programming time is 60 μs may be (100 mW/16)*4, which may be 25 mW. The energy required may be equal to 25 mW×60 μs, i.e., 1500 mW-μs. The energy left in capacitor bank 118 which storage device 104 may use to perform pre-erase and/or control write operations may be (100000−1500) mW-μs, i.e., 98500 mW-μs.

The energy not consumed from host 102 in a burst mode may be the power required for the other twelve dies in the meta-die on which the burst write is occurring, which may be equal to (100 mW/16)*12=48 mW, and the energy not consumed from host 102 as the other twelve dies are inactive during bursting may be equal to 48 mW×60 μs, i.e., 2880 mW-μs. As such, storage device 104 may use 2880 mW-μs to power up capacitors in capacitor bank 118.

The total energy which storage device 104 may consume for internal operations may be (98500 (i.e., the energy left in capacitor bank 118)+2880 mW-μs=101380 mW-μs. The erase time may be 3 ms and the power required to erase one physical block in a die may be (100 mW/16), i.e., 6 mW. The energy required to erase one physical block in a die may therefore be 6 mW×3 ms, i.e., 6 mW×3000 μs which is equal to 18000 mW-μs. The number of dies that may be powered up may be 101380 mW-μs/6000 mW-μs. i.e., five dies. Therefore, from this exemplary calculation an existing capacitor bank 118 may be used to perform erase operation on more than one die in an inactive meta-die while burst writes are ongoing in an active meta-die. There may also be sufficient window and energy to charge capacitor bank 118 when writes are ongoing in a burst mode as not all sixteen dies in a meta-die may be engaged in the burst write at any instant.

Storage device 104 may perform these processes based on a processor, for example, controller 108 executing software instructions stored by a non-transitory computer-readable medium, such as storage component/memory device 110. As used herein, the term “computer-readable medium” refers to a non-transitory memory device. Software instructions may be read into storage component 110 from another computer-readable medium or from another device. When executed, software instructions stored in storage component 110 may cause controller 108 to perform one or more processes described herein. Additionally, or alternatively, hardware circuitry may be used in place of or in combination with software instructions to perform one or more processes described herein. Thus, implementations described herein are not limited to any specific combination of hardware circuitry and software. System 100 may include additional components (not shown in this figure for the sake of simplicity). FIG. 1 is provided as an example. Other examples may differ from what is described in FIG. 1.

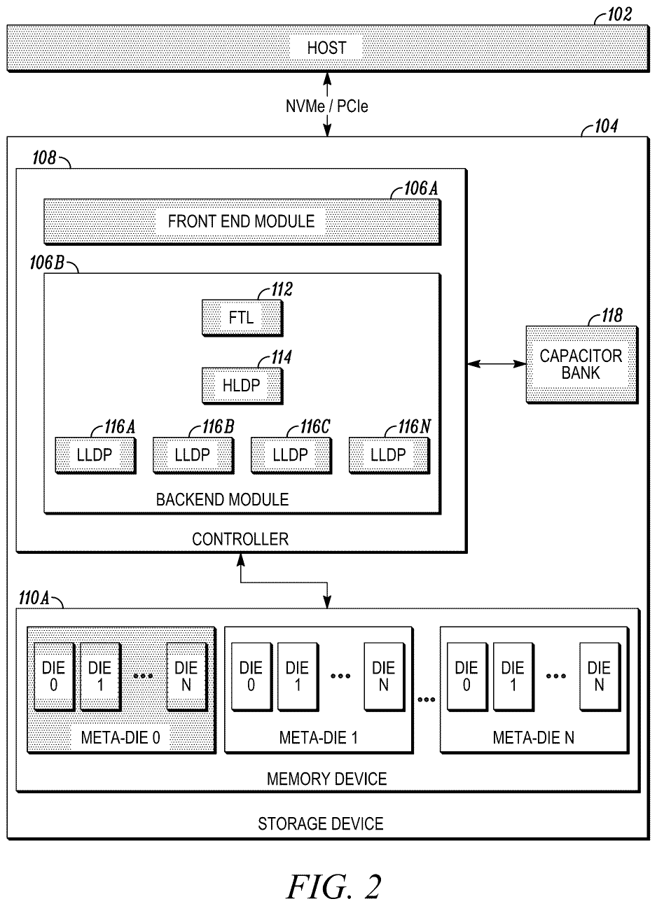

FIG. 2 is another schematic block diagram of an example system showing how host power is supplied to meta-dies in accordance with some implementations. When storage device 104 is writing data to a meta-die, host 102 may supply power to storage device 104. In a case where the peak power consumed by storage device is sufficient to only power one meta-die, storage device 104 may supply power to the meta-die on which it is performing host operation. As shown in FIG. 2, storage device 104 may supply power to meta-die 0, i.e., the meta-die on which it is performing host operation. The components of system 100 that are being supplied host power when storage device 104 is writing to meta-die 0 are shaded. Meta-dies 1-N are inactive and are thus not supplied host power. FIG. 2 is provided as an example. Other examples may differ from what is described in FIG. 2.

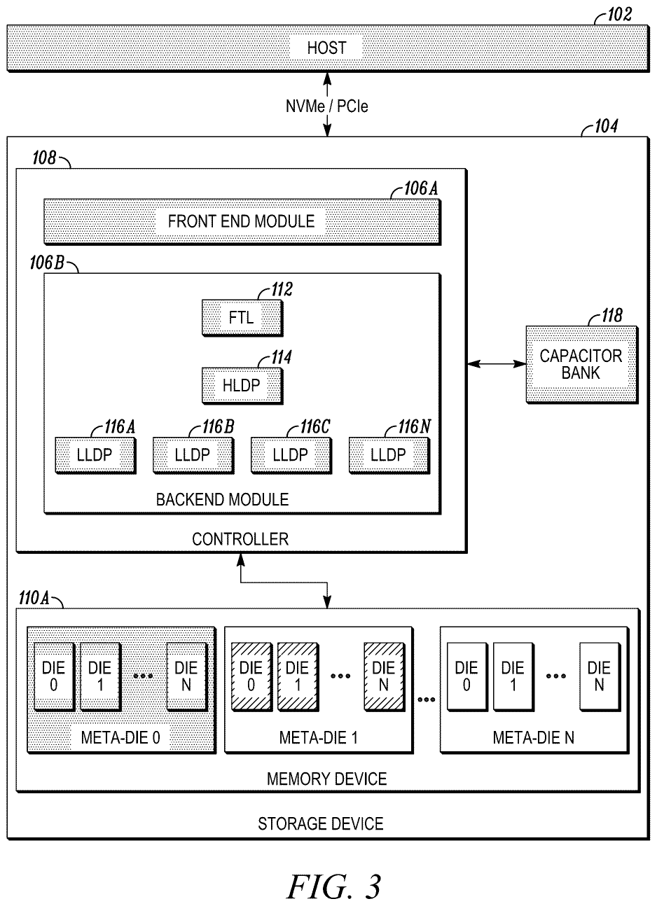

FIG. 3 is another schematic block diagram of an example system showing how host power and capacitor power are supplied to meta-dies in accordance with some implementations. Host power is being supplied to a meta-die on which storage device 104 is performing host operations. The components of the system that are being supplied host power when storage device 104 is writing to meta-die 0 are shaded. If controller 108 is performing a burst operation, as noted, a sub-section of the dies in meta-die 0 may be active during the SLC write. For example, four of the dies in meta-die 0 may be active during a burst write. As such, storage device 104 may ensure that capacitor bank 118 reserves 4-die worth of charge from power provided by host 102 to handle an ungraceful abort operation on the burst data.

Controller 108 may use the remaining 12-die worth of charge that would otherwise be reserved on capacitor bank 118, but that may be unused for burst operations, to begin an erase or control write operation on the meta block in meta die 1. The components of the system that are being supplied capacitor power when storage device 104 is writing to meta-die 0 are shown with slanted lines. As such, the dies in meta-die 1 are shown with slanted lines. The erase operation on the meta blocks in meta die 1 may occur in parallel with the burst write on meta-die 0. Storage device 104 may have opportunities to charge the capacitors in capacitor bank 118 with ongoing burst programming as the host power being consumed may be for only a sub-set of the dies (for example, 4-dies) in meta-die 0. As such, controller 108 may perform the parallel erase and burst write operation throughout the life cycle of storage device 104. As indicated above FIG. 3 is provided as an example. Other examples may differ from what is described in FIG. 3.

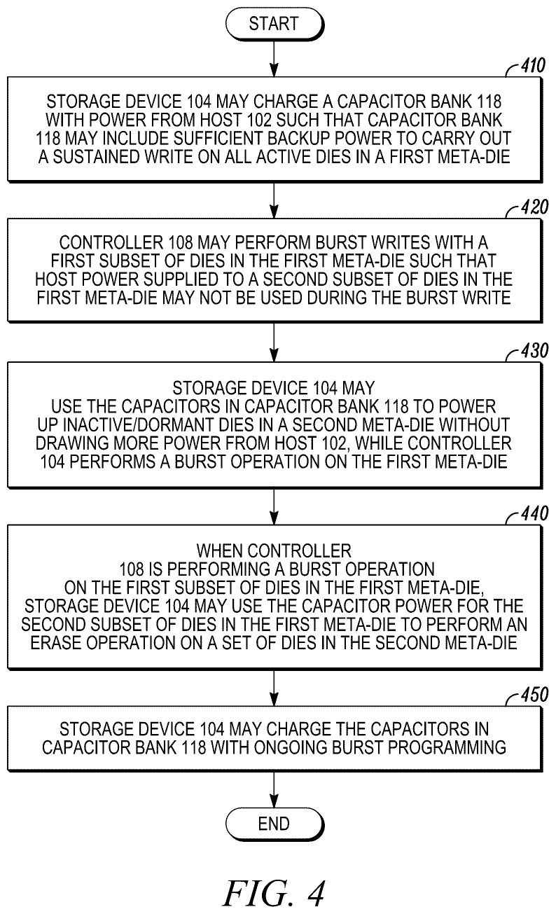

FIG. 4 is an example flow diagram for using power from a capacitor to boost the performance of a storage device in accordance with some implementations. At 410, storage device 104 may charge a capacitor bank 118 with power from host 102 such that capacitor bank 118 may include sufficient backup power to carry out a sustained write on all active dies in a first meta-die. At 420, controller 108 may perform burst writes with a first subset of dies in the first meta-die such that host power supplied to a second subset of dies in the first meta-die may not be used during the burst write. At 430, storage device 104 may use the capacitors in capacitor bank 118 to power up inactive/dormant dies in a second meta-die without drawing more power from host 102, while controller 104 performs a burst operation on the first meta-die. At 440, when controller 108 is performing a burst operation on the first subset of dies in the first meta-die, storage device 104 may use the capacitor power for the second subset of dies in the first meta-die to perform an erase operation on a set of dies in the second meta-die. At 450, storage device 104 may charge the capacitors in capacitor bank 118 with ongoing burst programming. As indicated above FIG. 4 is provided as an example. Other examples may differ from what is described in FIG. 4.

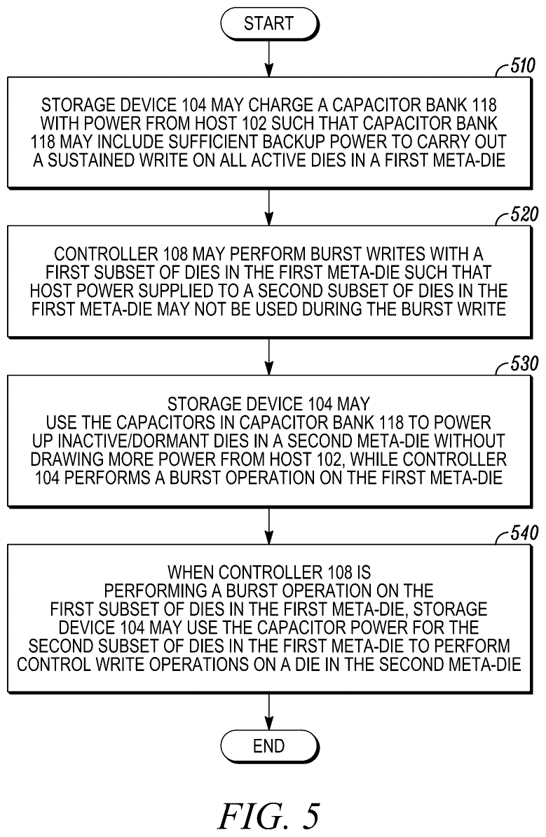

FIG. 5 is another example flow diagram for using power from a capacitor to boost the performance of a storage device in accordance with some implementations. At 510, storage device 104 may charge a capacitor bank 118 with power from host 102 such that capacitor bank 118 may include sufficient backup power to carry out a sustained write on all active dies in a first meta-die. At 520, controller 108 may perform burst writes with a first subset of dies in the first meta-die such that host power supplied to a second subset of dies in the first meta-die may not be used during the burst write. At 530, storage device 104 may use the capacitors in capacitor bank 118 to power up inactive/dormant dies in a second meta-die without drawing more power from host 102, while controller 104 performs a burst operation on the first meta-die. At 540, when controller 108 is performing a burst operation on the first subset of dies in the first meta-die, storage device 104 may use the capacitor power for the second subset of dies in the first meta-die to perform control write operations on a die in the second meta-die. As indicated above FIG. 5 is provided as an example. Other examples may differ from what is described in FIG. 5.

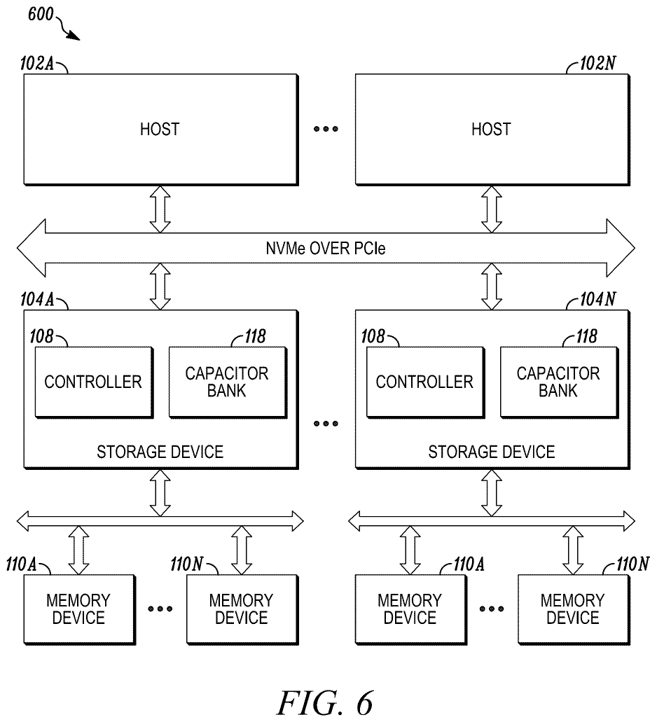

FIG. 6 is a diagram of an example environment in which systems and/or methods described herein are implemented. As shown in FIG. 6, Environment 600 may include hosts 102-102n (referred to herein as host(s) 102), and one or more storage devices 104a-104n (referred to herein as storage device(s) 104). Controller 108 may use power from a capacitor to boost the performance of storage device 104. Hosts 102 and storage devices 104 may communicate via Non-Volatile Memory Express (NVMe) over peripheral component interconnect express (PCI Express or PCIe), SD, or the like.

Devices of Environment 600 may interconnect via wired connections, wireless connections, or a combination of wired and wireless connections. For example, the network in FIG. 6 may include NVMe over Fabric(NVMe-oF) Internet Small Computer Systems Interface (iSCSI), Fibre Channel (FC), Fibre Channel Over Ethernet (FCoE) connectivity and any another type of next-generation network and storage protocols, a local area network (LAN), a wide area network (WAN), a metropolitan area network (MAN), a private network, an ad hoc network, an intranet, the Internet, a fiber optic-based network, a cloud computing network, or the like, and/or a combination of these or other types of networks.

The number and arrangement of devices and networks shown in FIG. 6 are provided as an example. In practice, there may be additional devices and/or networks, fewer devices and/or networks, different devices and/or networks, or differently arranged devices and/or networks than those shown in FIG. 6. Furthermore, two or more devices shown in FIG. 6 may be implemented within a single device, or a single device shown in FIG. 6 may be implemented as multiple, distributed devices. Additionally, or alternatively, a set of devices (e.g., one or more devices) of Environment 600 may perform one or more functions described as being performed by another set of devices of Environment 600.

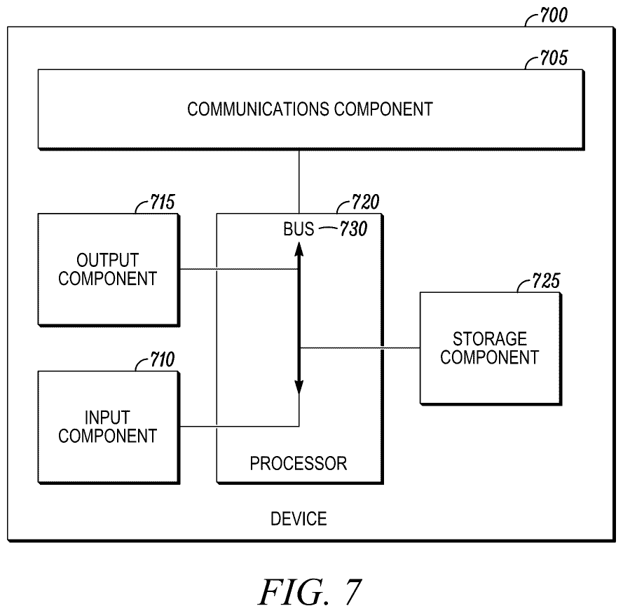

FIG. 7 is a diagram of example components of one or more devices of FIG. 1. In some implementations, host 102 may include one or more devices 700 and/or one or more components of device 700. Device 700 may include, for example, a communications component 705, an input component 710, an output component 715, a processor 720, a storage component 725, and a bus 730. Bus 730 may include components that enable communication among multiple components of device 700, wherein components of device 700 may be coupled to be in communication with other components of device 700 via bus 730.

Input component 710 may include components that permit device 700 to receive information via user input (e.g., keypad, a keyboard, a mouse, a pointing device, and a network/data connection port, or the like), and/or components that permit device 700 to determine the location or other sensor information (e.g., an accelerometer, a gyroscope, an actuator, another type of positional or environmental sensor). Output component 715 may include components that provide output information from device 700 (e.g., a speaker, display screen, and network/data connection port, or the like). Input component 710 and output component 715 may also be coupled to be in communication with processor 720.

Processor 720 may be a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some implementations, processor 720 may include one or more processors capable of being programmed to perform a function. Processor 720 may be implemented in hardware, firmware, and/or a combination of hardware and software.

Storage component 725 may include one or more memory devices, such as random-access memory, read-only memory (ROM), and/or another type of dynamic or static storage device (e.g., a flash memory, a magnetic memory, and/or optical memory) that stores information and/or instructions for use by processor 720. A memory device may include memory space within a single physical storage device or memory space spread across multiple physical storage devices. Storage component 725 may also store information and/or software related to the operation and use of device 700. For example, storage component 725 may include a hard disk (e.g., a magnetic disk, an optical disk, and/or a magneto-optic disk), a solid-state drive (SSD), a compact disc (CD), a digital versatile disc (DVD), a floppy disk, a cartridge, a magnetic tape, CXL device and/or another type of non-transitory computer-readable medium, along with a corresponding drive.

Communications component 705 may include a transceiver-like component that enables device 700 to communicate with other devices, such as via a wired connection, a wireless connection, or a combination of wired and wireless connections. The communications component 705 may permit device 700 to receive information from another device and/or provide information to another device. For example, communications component 705 may include an Ethernet interface, an optical interface, a coaxial interface, an infrared interface, a radio frequency (RF) interface, a universal serial bus (USB) interface, a Wi-Fi interface, and/or a cellular network interface that may be configurable to communicate with network components, and other user equipment within its communication range. Communications component 705 may also include one or more broadband and/or narrowband transceivers and/or other similar types of wireless transceiver configurable to communicate via a wireless network for infrastructure communications. Communications component 705 may also include one or more local area network or personal area network transceivers, such as a Wi-Fi transceiver or a Bluetooth transceiver.

Device 700 may perform one or more processes described herein. For example, device 700 may perform these processes based on processor 720 executing software instructions stored by a non-transitory computer-readable medium, such as storage component 725. As used herein, the term “computer-readable medium” refers to a non-transitory memory device. Software instructions may be read into storage component 725 from another computer-readable medium or from another device via communications component 705. When executed, software instructions stored in storage component 725 may cause processor 720 to perform one or more processes described herein. Additionally, or alternatively, hardware circuitry may be used in place of or in combination with software instructions to perform one or more processes described herein. Thus, implementations described herein are not limited to any specific combination of hardware circuitry and software.

The number and arrangement of components shown in FIG. 7 are provided as an example. In practice, device 700 may include additional components, fewer components, different components, or differently arranged components than those shown in FIG. 7. Additionally, or alternatively, a set of components (e.g., one or more components) of device 700 may perform one or more functions described as being performed by another set of components of device 700.

The foregoing disclosure provides illustrative and descriptive implementations but is not intended to be exhaustive or to limit the implementations to the precise form disclosed herein. One of ordinary skill in the art will appreciate that various modifications and changes can be made without departing from the scope of the present disclosure as set forth in the claims below. Accordingly, the specification and figures are to be regarded in an illustrative rather than a restrictive sense, and all such modifications are intended to be included within the scope of present teachings.

As used herein, the term “component” is intended to be broadly construed as hardware, firmware, and/or a combination of hardware and software. It will be apparent that systems and/or methods described herein may be implemented in different forms of hardware, firmware, and/or a combination of hardware and software.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set.

No element, act, or instruction used herein should be construed as critical or essential unless explicitly described as such. Also, as used herein, the articles “a” and “an” are intended to include one or more items and may be used interchangeably with “one or more.” Furthermore, as used herein, the term “set” is intended to include one or more items (e.g., related items, unrelated items, a combination of related items, unrelated items, and/or the like), and may be used interchangeably with “one or more.” The term “only one” or similar language is used where only one item is intended. Further, the phrase “based on” is intended to mean “based, at least in part, on” unless explicitly stated otherwise.

Moreover, in this document, relational terms such as first and second, top and bottom, and the like, may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, or “contains . . . a” does not, without more constraints, preclude the existence of additional identical elements in the process, method, article, or apparatus that comprises, has, includes, contains the element. The terms “substantially”, “essentially”, “approximately”, “about” or any other version thereof, are defined as being close to as understood by one of ordinary skill in the art, and in one non-limiting implementation, the term is defined to be within 10%, in another implementation within 5%, in another implementation within 1% and in another implementation within 0.5%. The term “coupled” as used herein is defined as connected, although not necessarily directly and not necessarily mechanically. A device or structure that is “configured” in a certain way is configured in at least that way but may also be configured in ways that are not listed.

We claim:

1. A storage device to use power from a capacitor to increase performance on the storage device, the storage device comprises:
a memory device including multiple meta-dies including a set of dies, wherein one meta-die is used for host operations at a time and is supplied host power and the other meta-dies are not supplied host power;
a capacitor to provide backup power to complete an ongoing operation during loss of host power on the storage device; and
a controller to use host power to perform a host burst write operation on a first subset of dies in a first meta-die, use power reserved by the capacitor for a second subset of dies in the first meta-die to power dies in a second meta-die, to use capacitor power to execute an erase operation on dies in the second meta-die in parallel with the host burst write operation on the first meta-die.

2. The storage device of claim 1, wherein the storage device charges the capacitor with power supplied by a host during the host burst write operation.

3. The storage device of claim 1, wherein the capacitor is charged with power to carry out a sustained write on active dies in a meta-die being used for host operations.

4. The storage device of claim 1, wherein the controller ensures that the capacitor reserves power to handle an ungraceful abort operation on burst data being written to the first subset of dies in the first meta-die.

5. The storage device of claim 1, wherein the controller determines that host burst write operation is to be carried out on the second meta-die based on pending host commands.

6. The storage device of claim 1, wherein a meta-die configuration includes sixteen dies, wherein the first subset of dies includes four dies, and the second subset of dies includes twelve dies.

7. The storage device of claim 1, wherein the controller uses the capacitor power to erase a third subset of dies on the second meta-die.

8. The storage device of claim 7, wherein the controller executes multiple burst sessions to fully program the first meta-die, wherein the controller uses unused capacitor power from a burst session to erase one or more dies in the third subset of dies on the second meta-die.

9. The storage device of claim 1, wherein the controller performs parallel erase operations on the dies in the second meta-die using capacitor power and host burst write operation on the first meta-die using host power during a life cycle of the storage device.

10. A storage device to use power from a capacitor to increase performance on the storage device, the storage device comprises:
a memory device including multiple meta-dies including a set of dies, wherein one meta-die is used for host operations at a time and is supplied host power and the other meta-dies are not supplied host power;
a capacitor to provide backup power to complete an ongoing operation during loss of host power on the storage device; and
a controller to use the host power to perform a host burst write operation on a first subset of dies in a first meta-die, use power reserved by the capacitor for a second subset of dies in the first meta-die to power a die in a second meta-die, to use capacitor power to execute a control write operation on the die in the second meta-die in parallel with the host burst write operation on a die in the first meta-die.

11. The storage device of claim 10, wherein the control write operation includes at least one of exclusive OR parity write operations and global address table delta write operations.

12. A method in a storage device for increasing performance on the storage device by using power from a capacitor on the storage device, the storage device comprises a controller to execute the method comprising:
providing backup power to a capacitor to complete an ongoing operation during loss of host power on the storage device;
using host power to perform a host burst write operation on a first subset of dies in the first meta-die;
using power reserved by the capacitor for a second subset of dies in the first meta-die to power dies in a second meta-die; and
using capacitor power to execute an erase operation on dies in the second meta-die in parallel with the host burst write operation on the first meta-die.

13. The method of claim 12, further comprising charging the capacitor with power supplied by a host during the host burst write operation.

14. The method of claim 12, further comprising charging the capacitor with power to carry out a sustained write on active dies in a meta-die being used for host operations.

15. The method of claim 12, further comprising ensuring that the capacitor reserves power to handle an ungraceful abort operation on burst data being written to the first subset of dies in the first meta-die.

16. The method of claim 12, further comprising determining that host burst write operation is to be carried out on the second meta-die based on pending host commands.

17. The method of claim 12, further comprising erasing a third subset of dies on the second meta-die using the capacitor power.

18. The method of claim 17, further comprising executing multiple burst sessions to fully program the first meta-die and using unused capacitor power from a burst session to erase the third subset of dies on the second meta-die.

19. The method of claim 12, further comprising executing a control write operation on a die in the second meta-die using capacitor power in parallel with the host burst write operation on a die in the first meta-die.

20. The method of claim 12, further comprising executing at least one of exclusive OR parity write operations and global address table delta write operations on a die in the second meta-die using capacitor power in parallel with the host burst write operation on a die in the first meta-die.
